(19) United States
(12) Patent Application Publication
(10) Pub. No.: US 2024/0235516 A1
(43) Pub. Date: Jul. 11, 2024

(54) FILTER DEVICE, ANTENNA DEVICE, AND ANTENNA MODULE

(71) Applicant: Murata Manufacturing Co., Ltd., Nagaokakyo-shi (JP)

(72) Inventor: Shinya TACHIBANA, Nagaokakyo-shi (JP)

(21) Appl. No.: 18/603,323

(22) Filed: Mar. 13, 2024

Related U.S. Application Data
(63) Continuation of application No. PCT/JP2022/039627, filed on Oct. 25, 2022.

(30) Foreign Application Priority Data
Nov. 2, 2021 (JP) 2021-179521

(51) Int. Cl. H03H 7/01; H03H 1/00

(52) U.S. Cl. CPC H03H 7/0115; H03H 2001/0021

(57) ABSTRACT

A filter device has a pass band in a band and an attenuation band in an band. The filter device includes first and second terminals, a first inductor connected to the first terminal, and an LC series resonator including a capacitor and a second inductor arranged in, among a first and second paths provided in parallel between the inductor and the terminal, the first path. The first inductor and the second inductor are magnetically coupled to each other.

### CROSS REFERENCE TO RELATED APPLICATIONS

This application claims the benefit of priority to Japanese Patent Application No. 2021-179521, filed on Nov. 2, 2021, and is a Continuation Application of PCT Application No. PCT/JP2022/039627, filed on Oct. 25, 2022. The entire contents of each application are hereby incorporated herein by reference.

### BACKGROUND OF THE INVENTION

### 1. Field of the Invention

The present disclosure relates to filter devices, antenna devices, and antenna modules, and more specifically to a technique to improve attenuation characteristics and bandpass characteristics.

### 2. Description of the Related Art

A high frequency circuit is provided with a filter device such as a band elimination filter or a band pass filter. Japanese Patent No. 6,531,824 discloses a filter device as an example of the filter device provided in a high frequency circuit. Such a filter device includes a first inductor and a first capacitor that define a first series circuit, and a second inductor that is connected in parallel with the first series circuit.

However, in the filter device disclosed in Japanese Patent No. 6,531,824, when an attenuation band due to parallel resonance and a pass band due to series resonance are brought close to each other, it is difficult to maintain both the attenuation characteristics and the bandpass characteristics at high levels.

### SUMMARY OF THE INVENTION

Example embodiments of the present invention provide filter devices that are each able to achieve good characteristics even when an attenuation band due to parallel resonance and a pass band due to series resonance are brought close to each other.

A filter device according to an example embodiment of the present invention has a pass band in a first frequency band and an attenuation band in a second frequency band lower than the first frequency band. The filter device includes a first terminal, a second terminal, a first inductor connected to the first terminal, and a series resonator including a first capacitor and a second inductor provided in, among a first path and a second path provided in parallel between the first inductor and the second terminal, the first path. The first inductor and the second inductor are magnetically coupled to each other.

In filter devices according to example embodiments of the present invention, the series resonator is provided in, among the first path and the second path provided in parallel between the first inductor and the second terminal, the first path, and the first inductor and the second inductor are magnetically coupled to each other. With such a configuration, the filter devices according to example embodiments of the present invention are each able to achieve high attenuation characteristics and bandpass characteristics even when the attenuation band due to parallel resonance and the pass band due to series resonance are brought close to each other.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit diagram of a filter device according to Example Embodiment 1 of the present invention.

FIG. 2 is a view illustrating a configuration of an antenna device according to Example Embodiment 1 of the present invention.

FIG. 3 is a graph explaining the reactance characteristics of the filter device according to Example Embodiment 1 of the present invention.

FIGS. 4A and 4B are equivalent circuit diagrams of the filter device according to Example Embodiment 1 of the present invention.

FIG. 5 is a graph showing an example of the insertion loss of the filter device according to Example Embodiment 1 of the present invention.

FIG. 6 is a graph showing an example of the reactance characteristics of the filter device according to Example Embodiment 1 of the present invention.

FIG. 7 is a graph showing an example of the reactance characteristics of the filter device according to Example Embodiment 1 of the present invention when the coupling coefficient is changed.

FIG. 8 is a perspective view of the filter device according to Example Embodiment 1 of the present invention.

FIG. 9 is an exploded plan view illustrating a configuration of the filter device according to Example Embodiment 1 of the present invention.

FIG. 10 is an exploded plan view illustrating a configuration of the filter device according to Example Embodiment 1 of the present invention when the winding direction of an inductor L1 and the winding direction of an inductor L2 are opposite to each other.

FIG. 11 is a view illustrating a configuration of an antenna module according to Example Embodiment 2 of the present invention.

FIG. 12 is a graph showing the isolation characteristics between antenna devices according to Example Embodiment 2 of the present invention.

FIG. 13 is a graph showing the radiation efficiency of each of the antenna devices according to Example Embodiment 2 of the present invention.

FIG. 14 is an external view of the antenna module according to Example Embodiment 2 of the present invention.

FIG. 15 is a circuit diagram of a filter device according to Example Embodiment 3 of the present invention.

FIG. 16 is a schematic view of the filter device according to Example Embodiment 3 of the present invention.

FIGS. 17A and 17B are graphs showing an example of the insertion loss and an example of the reactance characteristics of the filter device according to Example Embodiment 3 of the present invention.

FIG. 18 is a circuit diagram of a filter device according to Example Embodiment 4 of the present invention.

FIG. 19 is a schematic view of the filter device according to Example Embodiment 4 of the present invention.

FIG. 20 is a circuit diagram of a filter device according to Example Embodiment 5 of the present invention.

FIGS. 21A and 21B are graphs showing an example of the insertion loss of the filter device according to Example Embodiment 5 of the present invention.

FIGS. 22A and 22B are graphs showing an example of the reactance characteristics of the filter device according to Example Embodiment 5 of the present invention.

FIG. 23 is a circuit diagram of a filter device according to Example Embodiment 6 of the present invention.

FIGS. 24A and 24B are graphs showing an example of the insertion loss of the filter device according to Example Embodiment 6 of the present invention.

FIGS. 25A and 25B are graphs showing an example of the reactance characteristics of the filter device according to Example Embodiment 6 of the present invention.

FIG. 26 is a circuit diagram of a filter device according to a variation.

### DETAILED DESCRIPTION OF THE EXAMPLE EMBODIMENTS

Example embodiments of the present invention will be described in detail below with reference to the drawings. The same or equivalent components are denoted by the same reference signs in the drawings and the explanations thereof are not repeated.

### Example Embodiment 1

### Basic Configuration of Filter Device and Antenna Device

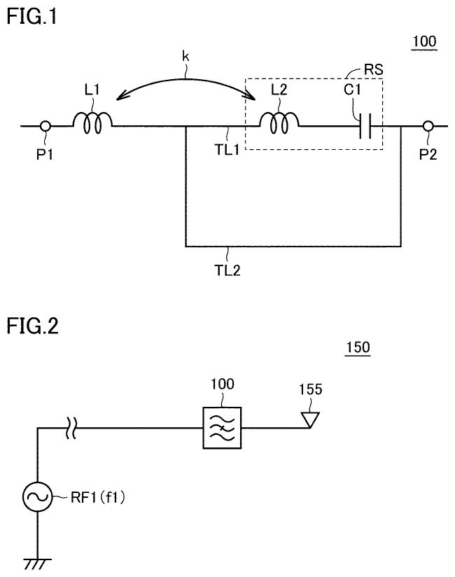

FIG. 1 is a circuit diagram of a filter device 100 according to Example Embodiment 1 of the present invention. FIG. 2 is a view illustrating a configuration of an antenna device 150 according to Example Embodiment 1. The filter device 100 is preferably a trap filter used in the antenna device 150 to impede and attenuate the passage of high frequency signals in a specific frequency band. The filter device 100 is also referred to as a band elimination filter.

The antenna device 150 includes a power feed circuit RF1, the filter device 100, and an antenna 155. The antenna device 150 is mounted on, for example, a portable terminal such as a cellular phone, a smartphone or a tablet, or a communication device such as, for example, a personal computer with a communication function. The power feed circuit RF1 supplies high frequency signals in a frequency band of an f1 band to the antenna 155. The antenna 155 is preferably, for example, a monopole antenna and is capable of radiating the high frequency signals in the f1 band supplied from the power feed circuit RF1 into the air as radio waves. The frequency band of the f1 band is, for example, n41 (about 2.5 GHz to about 2.7 GHZ).

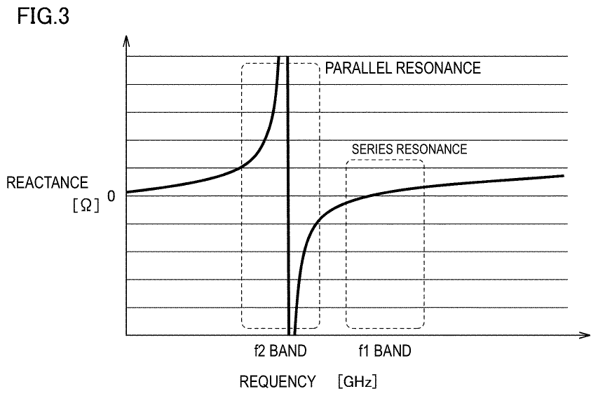

The filter device 100 works when the antenna device 150 is used near an antenna in a 2.4 GHz band (about 2.4 GHz to about 2.5 GHZ) of Wi-Fi (registered trademark). The filter device 100 is configured to attenuate high frequency signals in a frequency band of the 2.4 GHZ (an f2 band) and pass the high frequency signals in the frequency band of the f1 band. FIG. 3 is a graph explaining the reactance characteristics of the filter device 100 according to Example Embodiment 1. As shown in FIG. 3, in the filter device 100, the attenuation band due to parallel resonance is the frequency band of the f2 band, and the pass band due to series resonance is the frequency band of the f1 band.

The f1 band and the f2 band are frequency bands close to each other, as shown in FIG. 3. Whether or not the frequency bands are close to each other can be determined based on, for example, the band width and the center frequency with respect to the band width. For example, if the band width of a frequency end of the f1 band and a frequency end of the f2 band and the ratio of the center frequency with respect to the band width are within a predetermined range, it is determined that the f1 band and the f2 band are close to each other. Other methods may also be used to determine whether the frequency bands are close to each other.

The filter device 100 shown in FIG. 2 includes a terminal P1 and a terminal P2. The terminal P1 is used to connect the filter device 100 to a transmission line on the side of the power feed circuit RF1. The terminal P2 is used to connect the filter device 100 to a transmission line on the antenna 155 side.

When the power feed circuit RF1 supplies the high frequency signals to the antenna 155 via the filter device 100, the terminal P1 is an input terminal and the terminal P2 is an output terminal. When the high frequency signals received by the antenna 155 is transmitted via the filter device 100 to the circuit on the side of the power feed circuit RF1, the terminal P1 is an output terminal and the terminal P2 is an input terminal.

The filter device 100 includes an inductor L1, an inductor L2, and a capacitor C1, as shown in FIG. 1. A first path TL1 and a second path TL2 are provided between the inductor L1 and the terminal P2. The first path TL1 is provided with an LC series resonator RS in which the inductor L2 and the capacitor C1 are connected in series. The second path TL2 is a short path.

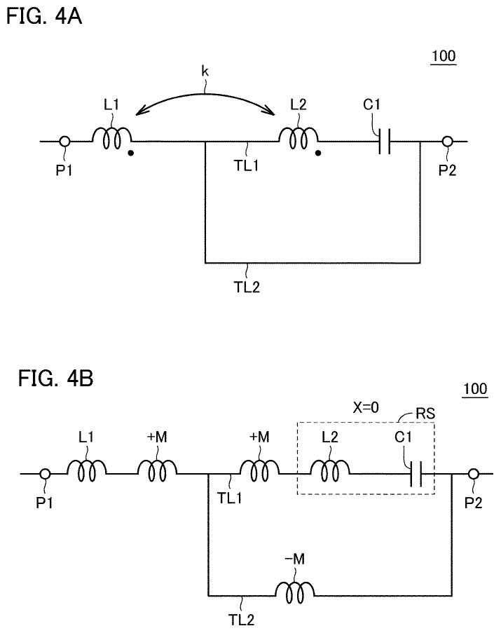

The inductor L1 and the inductor L2 are magnetically coupled to each other. Thus, a mutual inductance M is generated between the inductor L1 and the inductor L2. Due to the generated mutual inductance M, an inductance is caused in each of the first path TL1 and the second path TL2, thus defining a parallel resonator. FIGS. 4A and 4B are equivalent circuit diagrams of the filter device 100 according to Example Embodiment 1.

The circuit diagram shown in FIG. 4A illustrates a circuit of the filter device 100 when the winding directions of the respective coils defining the inductor L1 and the inductor L2 are the same. The equivalent circuit diagram shown in FIG. 4B illustrates an equivalent circuit of the circuit of the filter device 100 shown in FIG. 4A, wherein a mutual inductance +M is indicated in the first path TL1 and a mutual inductance −M is indicated in the second path TL2.

Here, the series resonant frequency of the LC series resonator RS is expressed as: f0=1/(2π(L2×C1) 1/2). At the series resonant frequency f0, in the LC series resonator RS, the combined reactance X of the inductor L2 and the capacitor C1 in the LC series resonator RS is 0 (zero) (X=0). Therefore, at the series resonant frequency f0, where the combined reactance X of the LC series resonator RS is 0 (zero), the filter device 100 functions as a parallel resonator caused by the mutual inductances −M and +M. The resonant frequency of such a parallel resonator matches the series resonant frequency f0 of the LC series resonator RS, which is the parallel resonant frequency of the attenuation band (f2 band) of the filter device 100.

In a conventional filter device, all components such as inductors and capacitors affect the parallel resonant frequency in the attenuation band. Therefore, in a conventional filter device, all components must be considered to design the parallel resonant frequency in the attenuation band. However, in the filter device 100, the parallel resonant frequency in the attenuation band (f2 band) can be designed only by considering the inductor L2 and the capacitor C1 defining the LC series resonator RS. Therefore, the filter device 100 has a very superior configuration in terms of structural design.

Specifically, for example, the filter device 100 was simulated with the inductor L1 set to about 1.0 nH, the inductor L2 set to about 2.0 nH, the capacitor C1 set to about 2.2 pF, and a coupling coefficient K set to about 0.5. When the series resonant frequency f0 of the LC series resonator RS is calculated with the inductor L2 set to about 2.0 nH and the capacitor C1 set to about 2.2 pF, the result is about 2.4 GHZ, which coincides with about 2.4 GHz, the parallel resonant frequency (center frequency) of the attenuation band (f2 band) of the filter device 100. The series resonant frequency (center frequency) of the pass band (f1 band) of the filter device 100 is about 2.77 GHz. In the filter device 100, it is preferred that the inductance of the inductor L1 be smaller than the inductance of the inductor L2. Thus, the overall loss of the filter device 100 can be reduced.

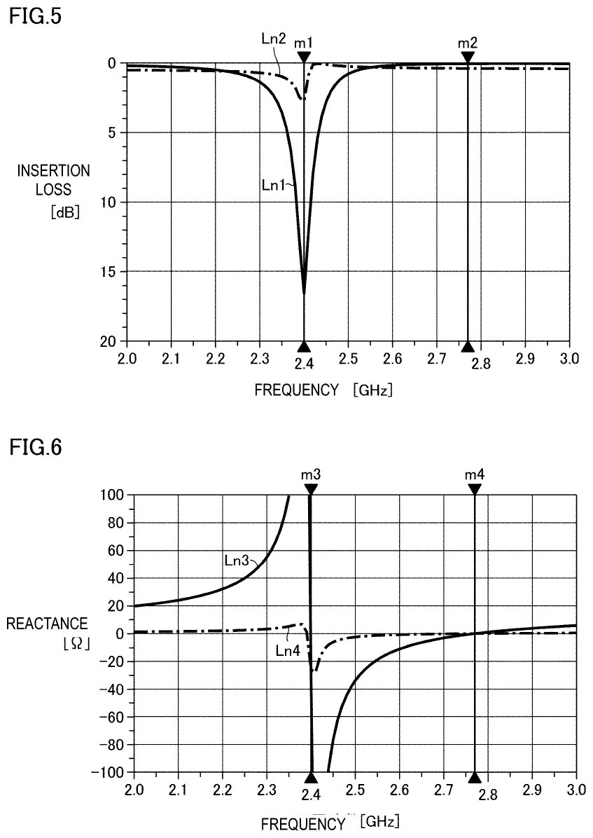

FIG. 5 is a graph showing an example of the insertion loss of the filter device 100 according to Example Embodiment 1. In FIG. 5, the horizontal axis is the frequency and the vertical axis is the insertion loss. FIG. 6 is a graph showing an example of the reactance characteristics of the filter device 100 according to Example Embodiment 1. In FIG. 6, the horizontal axis is the frequency and the vertical axis is the reactance. Here, the insertion loss is the ratio of the power output from the filter device 100 to the power input to the filter device 100.

In addition to a line Ln1 indicating the insertion loss of the filter device 100, FIG. 5 also shows a line Ln2 indicating the insertion loss of a filter device to be compared. Although not shown in the drawing, in the filter device to be compared, an inductor Lb is connected in parallel with an LC series resonator consisting of an inductor La and a capacitor Ca. The filter device to be compared was simulated with the inductor Lb set to about 0.069 nH, the inductor La set to about 42.19 nH, the capacitor Ca set to about 0.1 pF, and a coupling coefficient K2 between the inductor Lb and the inductor La set to about 0.5. In the filter device to be compared, the parallel resonant frequency (center frequency) in the attenuation band (f2 band) is also about 2.4 GHZ and the series resonant frequency (center frequency) in the pass band (f1 band) is also about 2.77 GHZ.

The mark m1 shown in FIG. 5 indicates the location of the parallel resonant frequency (center frequency) at about 2.4 GHz; at the mark m1, the insertion loss of the line Ln1 is about 16.6 dB, while the insertion loss of the line Ln2 is about 2.75 dB. Therefore, the filter device 100 achieves sufficient attenuation characteristics in the attenuation band (f2 band), while the filter device to be compared does not achieve sufficient attenuation characteristics.

The mark m2 shown in FIG. 5 indicates the location of the series resonant frequency (center frequency) at about 2.77 GHz; at the mark m2, the insertion loss of the line Ln1 is about 0.068 dB, while the insertion loss of the line Ln2 is about 0.404 dB. Therefore, the filter device 100 achieves higher bandpass characteristics in the pass band (f1 band) than the filter device to be compared.

In addition to a line Ln3 indicating the reactance characteristics of the filter device 100, FIG. 6 also shows a line Ln4 indicating the reactance characteristics of the filter device to be compared. The mark m3 shown in FIG. 6 indicates the location of the parallel resonant frequency (center frequency) at about 2.4 GHz; at the mark m3, the reactance of the line Ln3 changes significantly compared to the reactance of the line Ln4. Therefore, the filter device 100 achieves sufficient attenuation characteristics in the attenuation band (f2 band), while the filter device to be compared does not achieve sufficient attenuation characteristics.

The mark m4 shown in FIG. 6 indicates the location of the series resonant frequency (center frequency) at about 2.77 GHZ, and the reactance of the line Ln3 at the mark m4 is substantially 0 (zero). Therefore, the filter device 100 achieves sufficient bandpass characteristics in the pass band (f1 band).

The filter device 100 achieves sufficient attenuation characteristics and bandpass characteristics when the attenuation band (f2 band) due to parallel resonance and the pass band (f1 band) due to series resonance are brought close to each other, as shown in FIGS. 5 and 6. On the other hand, the filter device to be compared does not achieve sufficient attenuation characteristics and bandpass characteristics when the attenuation band (f2 band) due to parallel resonance and the pass band (f1 band) due to series resonance are brought close to each other, as shown in FIGS. 5 and 6. Furthermore, in the filter device to be compared, the attenuation band (f2 band) due to parallel resonance and the pass band (f1 band) due to series resonance can only be brought close to each other if the inductor Lb is set to an extremely small value of, for example, about 0.069 nH while the inductor La is set to a large value of, for example, about 42.19 nH. Therefore, in reality, it is difficult to obtain a configuration in which the coupling coefficient K2 between the inductor Lb and the inductor La is set to about 0.5.

As described above, in the filter device 100, the parallel resonant frequency in the attenuation band (f2 band) is determined by the inductor L2 and the capacitor C1 that define the LC series resonator RS. Therefore, the filter device 100 can change the series resonant frequency in the pass band (f1 band) by changing the coupling coefficient between the inductor L1 and the inductor L2, and can bring the pass band (f1 band) due to series resonance closer to the attenuation band (f2 band) due to parallel resonance. In other words, the filter device 100 can realize a narrow-band filter device whose attenuation characteristics change steeply in the vicinity of the parallel resonant frequency in the attenuation band (f2 band).

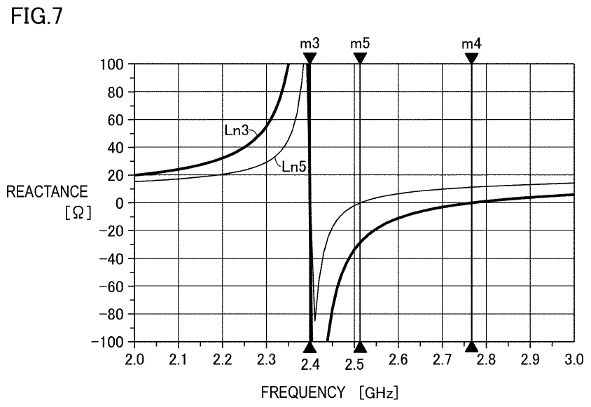

FIG. 7 is a graph showing an example of the reactance characteristics of the filter device 100 according to Example Embodiment 1 when the coupling coefficient K is changed. In FIG. 7, the horizontal axis represents the frequency and the vertical axis represents the reactance.

In addition to the line Ln3 indicating the reactance characteristics of the filter device 100 when the coupling coefficient K set to about 0.5, FIG. 7 also shows a line Ln5 indicating the reactance characteristics of the filter device 100 when the coupling coefficient K set to about 0.3. Except for the different coupling coefficients K, for example, both filter devices 100 were simulated with the inductor L1 set to about 1.0 nH, the inductor L2 set to about 2.0 nH, and the capacitor C1 set to about 2.2 pF.

At the mark m3 shown in FIG. 7, the reactance of the line Ln5 changes more steeply than the reactance of the line Ln3. When the coupling coefficient K is equal to about 0.5, the reactance of the line Ln3 is substantially 0 (zero) Q at the mark m4 and the series resonant frequency in the pass band (f1 band) is about 2.77 GHz. On the other hand, when the coupling coefficient K is equal to about 0.3, the reactance of the line Ln4 is substantially 0 (zero) Q at the mark m5 and the series resonant frequency in the pass band (f1 band) is about 2.51 GHZ, which is closer to the parallel resonant frequency (center frequency) at about 2.4 GHz. In other words, the filter device 100 can bring the series resonant frequency (center frequency) closer to the parallel resonant frequency (center frequency) by reducing the coupling coefficient K. As the coupling coefficient K becomes smaller, the mutual inductance M itself also becomes smaller; therefore, it is preferred that the coupling coefficient K is, for example, about 0.1 or more in the filter device 100.

Example of Element in which Filter Device is Integrated

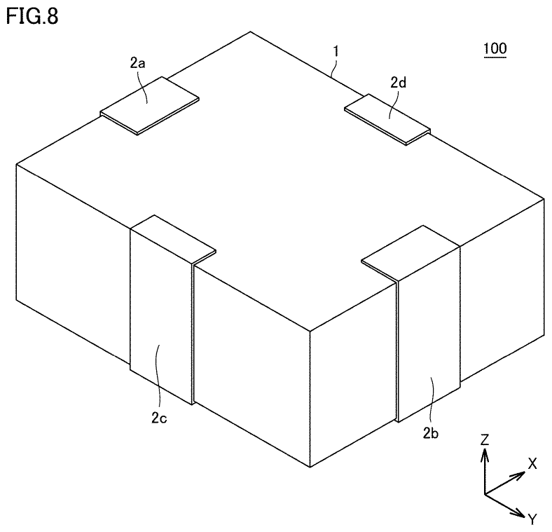

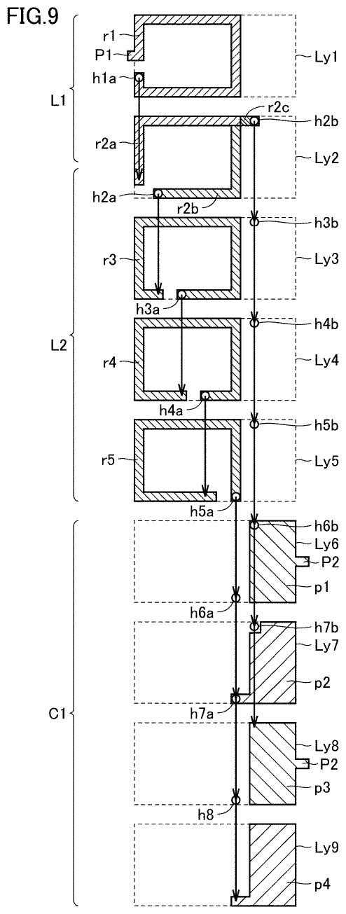

An example of a structure of an element in which the filter device 100 according to example embodiment 1 is integrated will be described below with reference to the drawings. FIG. 8 is a perspective view of the filter device according to Example Embodiment 1. FIG. 9 is an exploded plan view illustrating a configuration of the filter device 100 according to Example Embodiment 1.

The filter device 100 is integrated as a chip component, for example, in which the inductor L1 and the LC series resonator RS shown in FIG. 1 are provided in an insulator 1 (housing) obtained by stacking dielectric layers, and outer electrodes 2a to 2d are located on an outer side portion of the insulator 1. The terminal P1 is connected to the outer electrode 2a (first outer electrode) and the terminal P2 is connected to the outer electrode 2b (second outer electrode). In the filter device 100, the short side direction is an X direction, the long side direction is a Y direction, and the height direction is a Z direction; the stacking direction of the dielectric layers is the Z direction. The outer electrodes 2c and 2d are GND electrodes with no connection to the internal circuit. Furthermore, the filter device 100 shown in FIG. 8 indicates a four-terminal configuration with the outer electrodes 2a to 2d provided on the outer side portion of the insulator 1, but the present disclosure also includes a two-terminal configuration with only the outer electrodes 2a and 2b provided on the outer side portion of the insulator 1.

The filter device 100 is defined by a stacking process and is defined by stacking a plurality of dielectric layers Ly1 to Ly9 substrates (hereinafter referred to simply as dielectric layers Ly1 to Ly9) shown in FIG. 9. Each of the dielectric layers Ly1 to Ly9 is preferably, for example, a ceramic green sheet, on which a wiring pattern is defined by applying a conductive paste (e.g., Ni paste) by a screen printing method.

A wiring pattern r1 defining a portion of the inductor L1 is provided on the dielectric layer Ly1. One end of the wiring pattern r1 is connected to the terminal P1 and the other end is connected to a via conductor h1a.

A wiring pattern r2a defining a portion of the inductor L1 is provided on the dielectric layer Ly2. One end of the wiring pattern r2a is connected to the via conductor h1a, and the other end is connected to a wiring pattern r2b as well as to a wiring pattern r2c of the second path TL2. The wiring pattern r2b defines a portion of the inductor L2, and a via conductor h2a is connected to the wiring pattern r2b at an end opposite to the wiring pattern r2a. A via conductor h2b is connected to the wiring pattern r2c of the second path TL2 at an end opposite to the wiring pattern r2a.

A wiring pattern r3 defining a portion of the inductor L2 is provided on the dielectric layer Ly3. One end of the wiring pattern r3 is connected to the via conductor h2a and the other end is connected to a via conductor h3a. The dielectric layer Ly3 is provided with a via conductor h3b connected to the via conductor h2b.

A wiring pattern r4 defining a portion of the inductor L2 is provided on the dielectric layer Ly4. One end of the wiring pattern r4 is connected to the via conductor h3a and the other end is connected to a via conductor h4a. The dielectric layer Ly4 is provided with a via conductor h4b connected to the via conductor h3b.

A wiring pattern r5 defining a portion of the inductor L2 is provided on the dielectric layer Ly5. One end of the wiring pattern r5 is connected to the via conductor h4a and the other end is connected to a via conductor h5a. The dielectric layer Ly5 is provided with a via conductor h5b connected to the via conductor h4b.

An electrode pattern p1 defining a portion of the capacitor C1 is provided on the dielectric layer Ly6, at a position that does not overlap with the inductors L1 and L2 when viewed from the stacking direction. The electrode pattern p1 is connected to the terminal P2 and to a via conductor h6b. The via conductor h6b is connected to the via conductor h5b and electrically connects the electrode pattern p1 to the wiring pattern r2c of the second path TL2. The dielectric layer Ly6 is provided with a via conductor h6a connected to the via conductor h5a.

An electrode pattern p2 defining a portion of the capacitor C1 is provided on the dielectric layer Ly7, at a position that does not overlap with the inductors L1 and L2 when viewed from the stacking direction. The electrode pattern p2 is connected to a via conductor ha and electrically connected to the inductor L2, but is not directly electrically connected to the electrode pattern p1. The dielectric layer Ly7 is provided with a via conductor h7b connected to the via conductor h6b.

An electrode pattern p3 defining a portion of the capacitor C1 is provided on the dielectric layer Ly8, at a position that does not overlap with the inductors L1 and L2 when viewed from the stacking direction. The electrode pattern p3 is connected to the terminal P2 and to the via conductor h7b. The electrode pattern p1 and the electrode pattern p3 are electrically connected via the via conductor h7b. The dielectric layer Ly8 is provided with a via conductor h8 connected to the via conductor h7a.

An electrode pattern p4 defining a portion of the capacitor C1 is provided on the dielectric layer Ly9, at a position that does not overlap with the inductors L1 and L2 when viewed from the stacking direction. The electrode pattern p4 is connected to the via conductor h8 and electrically connected to the electrode pattern p2, but is not directly electrically connected to the electrode patterns p1 and p3.

The wiring pattern r1 provided on the dielectric layer Ly1 and the wiring pattern r2a provided on the dielectric layer Ly2 define a winding shape when viewed from the stacking direction, and define the inductor L1. The wiring pattern r2b provided on the dielectric layer Ly2 and the wiring patterns r3 to r5 provided on the dielectric layers Ly3 to Ly5 define a winding shape when viewed from the stacking direction, and define the inductor L2. The inductor L1 and the inductor L2 are arranged opposing each other, and the opening of the inductor L1 at least partially overlaps with the opening of the inductor L2 when viewed from the stacking direction. Therefore, if the overlap portion between the opening of the inductor L1 and the opening of the inductor L2 is increased when viewed from the stacking direction, the coupling coefficient between the inductor L1 and the inductor L2 increases, and the mutual inductance M due to magnetic coupling increases.

The filter device 100 is preferably stacked in the order of the inductor L1, the inductor L2, and the capacitor C1 when viewed from the stacking direction as shown in FIG. 9, but may be stacked in other orders, such as in the order of the inductor L2, the inductor L1, and the capacitor C1. In FIG. 9, by changing the stacking order of the inductor L1 and the inductor L2 and providing the capacitor C1 on the side of the inductor L1, the number of the via conductors h2b to h5b defining a portion of the second path TL2 can be reduced and the length of the second path TL2 can be shortened.

It is preferred that the second path TL2, which is the short path shown in FIG. 1, is a path connecting the connection portion between the inductor L1 and the inductor L2 to the capacitor C1, and ESL (Equivalent Series Inductance), which is the parasitic inductance generated in such a path, is smaller than the mutual inductance M. In other words, by making the inductance of the second path TL2 smaller than the mutual inductance M between the inductor L1 and the inductor L2, the second path TL2 can be regarded as a short path.

In the stacked structure shown in FIG. 9, the second path TL2 is defined by the via conductors h2b to h5b connecting the stacked layers, and the wiring pattern r2c. The second path TL2, which is a short path, may contain some resistance component (R component), but a smaller resistance component (R component) can improve the Q value of the filter device 100.

If the filter device 100 is formed in a stacking process, for example, the dielectric material can be different for the inductors L1 and L2 and the capacitor C1, and for such a purpose, as shown in FIG. 9, the layers defining the inductors L1 and L2 (the dielectric layers Ly1 to Ly5) and the layers defining the capacitor C1 (the dielectric layers Ly6 to Ly 9) must be separated. On the other hand, if the filter device 100 is defined by, for example, photolithography, the capacitor C1 can be located side by side with respect to the inductor L1 or the inductor L2 without separating the layers defining the inductors L1 and L2 and the layer defining the capacitor C1.

In the filter device 100 shown in FIG. 9, the wiring patterns r1, r2a, r2b, and r3 to r5 are provided so that the winding direction of the inductor L1 is the same as the winding direction of the inductor L2. Therefore, the filter device 100 has a structure that makes it easy to increase the coupling coefficient between the inductor L1 and the inductor L2.

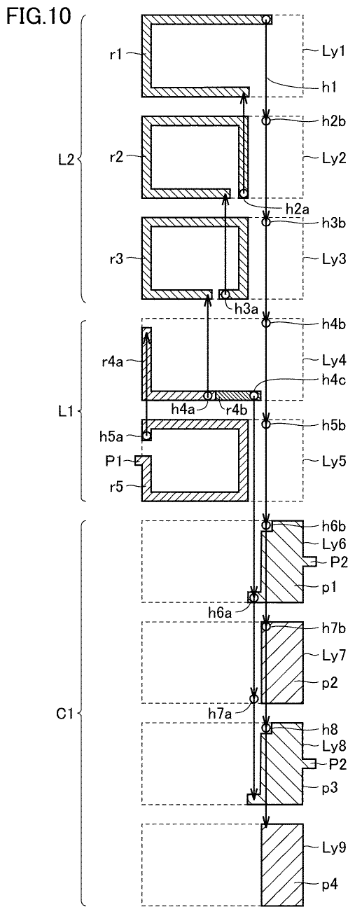

However, the filter device 100 is not limited to cases where the winding direction of the inductor L1 and the winding direction of the inductor L2 are the same, but the winding direction of the inductor L1 and the winding direction of the inductor L2 may be opposite. FIG. 10 is an exploded plan view illustrating a configuration of the filter device 100 according to Example Embodiment 1 when the winding direction of the inductor L1 and the winding direction of the inductor L2 are opposite to each other. The filter device 100 shown in FIG. 10 is stacked in the order of the inductor L2, the inductor L1, and the capacitor C1, when viewed from the stacking direction.

A wiring pattern r1 defining a portion of the inductor L2 is provided on the dielectric layer Ly1. One end of the wiring pattern r1 is connected to a via conductor h1 and the other end is connected to a via conductor h2a of the dielectric layer Ly2.

A wiring pattern r2 defining a portion of the inductor L2 is provided on the dielectric layer Ly2. One end of the wiring pattern r2 is connected to the via conductor h2a and the other end is connected to a via conductor h3a of the dielectric layer Ly3. The dielectric layer Ly2 is provided with a via conductor h2b connected to the via conductor h1.

A wiring pattern r3 defining a portion of the inductor L2 is provided on the dielectric layer Ly3. One end of the wiring pattern r3 is connected to the via conductor h3a and the other end is connected to a via conductor h4a of the dielectric layer Ly4. The dielectric layer Ly3 is provided with a via conductor h3b connected to the via conductor h2b.

A wiring pattern r4a defining a portion of the inductor L1 is provided on the dielectric layer Ly4. One end of the wiring pattern r4a is connected to a via conductor h5a on the dielectric layer Ly4, and the other end is connected to the via conductor h4a as well as to a wiring pattern r4b of the second path TL2. A via conductor h4c is connected to the wiring pattern r4b of the second path TL2 at an end opposite to the wiring pattern r4a. The dielectric layer Ly4 is provided with a via conductor h4b connected to the via conductor h3b.

A wiring pattern r5 defining a portion of the inductor L1 is provided on the dielectric layer Ly5. One end of the wiring pattern r5 is connected to the via conductor h5a and the other end is connected to the terminal P1. The dielectric layer Ly5 is provided with a via conductor h5b connected to the via conductor h4b.

An electrode pattern p1 defining a portion of the capacitor C1 is provided on the dielectric layer Ly6 at a position that does not overlap with the inductors L1 and L2 when viewed from the stacking direction. The electrode pattern p1 is connected to the terminal P2 and to a via conductor h6a. The via conductor h6a is connected to the via conductor h4c and electrically connects the electrode pattern p1 to the wiring pattern r4b of the second path TL2. The dielectric layer Ly6 is provided with a via conductor h6b connected to the via conductor h5b.

An electrode pattern p2 defining a portion of the capacitor C1 is provided on the dielectric layer Ly7, at a position that does not overlap with the inductors L1 and L2 when viewed from the stacking direction. The electrode pattern p2 is connected to a via conductor h7b and electrically connected to the inductor L2, but is not directly electrically connected to the electrode pattern p1. The dielectric layer Ly7 is provided with a via conductor h7a connected to the via conductor h6a.

An electrode pattern p3 defining a portion of the capacitor C1 is provided on the dielectric layer Ly8, at a position that does not overlap with the inductors L1 and L2 when viewed from the stacking direction. The electrode pattern p3 is connected to the terminal P2 and to the via conductor h7a. The electrode pattern p1 and the electrode pattern p3 are electrically connected via the via conductor h7a. The dielectric layer Ly8 is provided with a via conductor h8 connected to the via conductor h7b.

An electrode pattern p4 defining a portion of the capacitor C1 is provided on the dielectric layer Ly9, at a position that does not overlap with the inductors L1 and L2 when viewed from the stacking direction. The electrode pattern p4 is connected to the via conductor h8 and electrically connected to the electrode pattern p2, but is not electrically connected to the electrode patterns p1 and p3.

The wiring pattern r5 provided on the dielectric layer Ly5 and the wiring pattern r4a provided on the dielectric layer Ly4 define a winding shape when viewed from the stacking direction, and define the inductor L1. The wiring patterns r1 to r3 provided on the dielectric layers Ly1 to Ly3 define a winding shape when viewed from the stacking direction, and define the inductor L2. The inductor L1 and the inductor L2 are arranged opposing each other, and the opening of the inductor L1 at least partially overlaps with the opening of the inductor L2 when viewed from the stacking direction.

As shown in FIG. 10, in the inductor L1, the wiring pattern r5 and the wiring pattern r4a have a counterclockwise winding direction from the dielectric layer Ly5 toward the dielectric layer Ly1, while in the inductor L2, the wiring patterns r1 to r3 have a clockwise winding direction. Therefore, unlike the equivalent circuit diagram shown in FIG. 4B, a mutual inductance −M and a mutual inductance +M are generated in the first path TL1 and the second path TL2, respectively.

When the winding direction of the inductor L1 and the winding direction of the inductor L2 are opposite to each other, the wiring pattern r2a defining a portion of the inductor L1 is not provided on the same layer as the wiring pattern r2b defining a portion of the inductor L2, such as on the dielectric layer Ly2 shown in FIG. 9. Therefore, the inductor L1 and the inductor L2 have a relatively high degree of freedom, which makes it easier to adjust their respective inductances.

As described above, the filter device 100 of Example Embodiment 1 is a filter device having a pass band in the f1 band (first frequency band) and an attenuation band in the f2 band (second frequency band) lower than the f1 band. The filter device 100 includes the terminal P1 (first terminal), the terminal P2 (second terminal), the inductor L1 (first inductor) connected to the terminal P1, and the LC series resonator RS including the capacitor C1 (first capacitor) and the inductor L2 (second inductor) disposed in, among the first path TL1 and the second path TL2 provided in parallel between the inductor L1 and the terminal P2, the first path TL1. The inductor L1 and the inductor L2 are magnetically coupled to each other.

Thus, the filter device 100 according to Example Embodiment 1 can achieve both high attenuation characteristics and bandpass characteristics even when the attenuation band due to parallel resonance and the pass band due to series resonance are brought close to each other.

It is preferred that the inductance of the second path TL2 is smaller than the mutual inductance M between the inductor L1 and the inductor L2. Thus, the second path TL2 can be regarded as a short path, so that the design of the parallel resonant frequency becomes easy.

It is preferred that the inductance of the inductor L1 is smaller than the inductance of inductor L2. Thus, the overall loss of the filter device 100 can be reduced.

Preferably, the terminal P1 and the terminal P2 are electrically connected to the first outer electrode and the second outer electrode provided on the housing, respectively, and the inductor L1 and the LC series resonator RS are provided within the housing. Thus, the filter device 100 can be integrated as, for example, a chip component. By miniaturizing the filter device 100, the number of components in the antenna device incorporating the filter device 100 can be reduced, and the amount of solder to be used can also be reduced.

The housing is, for example, an insulator, and the inductor L1 and the LC series resonator RS are preferably defined by a plurality of conductor patterns in the insulator. The inductor L1 is electrically connected to the terminal P1 and includes one or more layers of the wiring patterns r1 and r2a (first conductor pattern). The inductor L2 is electrically connected to the terminal P2 and includes one or more layers of the wiring patterns r2b and r3 to r5 (second conductor pattern). It is preferred that the capacitor C1 be electrically connected to the wiring pattern r2c extending from the wiring patterns r2a and r2b. Thus, the filter device 100 can be integrated as a chip component of a stacked structure. Furthermore, since the number of layers defining the second path TL2 can be reduced by extending the wiring pattern r2c from the middle of the wiring patterns of the inductors L1 and L2, the filter device 100 can be made as a low height, low cost, and environmentally friendly component.

Preferably, within the insulator, the substrates on which the wiring patterns r2b and r3 to r5 (second conductor pattern) are provided are stacked on the substrates on which the wiring patterns r1 and r2a (first conductor pattern) are located so that the inductor L1 and the inductor L2 are arranged opposing each other, and the opening of the inductor L1 at least partially overlaps with the opening of the inductor L2 when viewed from the stacking direction of the insulator. Thus, the coupling coefficient between the inductor L1 and the inductor L2 increases, so that the mutual inductance M due to magnetic coupling can be increased.

The capacitor C1 is preferably arranged on a different layer from the layer on which the inductor L1 and the inductor L2 are arranged. Thus, the capacitor C1 and the inductor L1 and inductor 12 can be made of dielectric material.

The capacitor C1 is preferably located on the side of the inductor L1 when viewed from the stacking direction of the insulator. Thus, the length of the second path TL2 connecting the capacitor C1 and the inductor L1 can be shortened.

The antenna device 150 of Example Embodiment 1 is capable of radiating radio waves in the f1 band. The antenna device 150 includes the antenna 155, the power feed circuit RF1 that supplies high frequency signals to the antenna 155, and the above-described filter device 100 provided between the antenna 155 and the power feed circuit RF1.

Thus, the antenna device 150 according to Example Embodiment 1 can pass the f1 band and attenuate the radio waves in the f2 band even when the f1 band and the f2 band are brought close to each other.

### Example Embodiment 2

In Example Embodiment 1, the antenna device 150 including the antenna 155 has been described. In Example Embodiment 2, an antenna module 200 including an antenna device 160 will be described in addition to the antenna device 150 according to Example Embodiment 1. In the description of the antenna module 200 of Example Embodiment 2, the components that are the same as or corresponding to those of the antenna device 150 of Example Embodiment 1 are not described repeatedly.

### Basic Configuration of Antenna Module

FIG. 11 is a view illustrating a configuration of the antenna module 200 according to Example Embodiment 2 of an example embodiment. The antenna module 200 includes the antenna device 150 and the antenna device 160. The antenna device 160 includes a power feed circuit RF2 and an antenna 165. The antenna module 200 is mounted on, for example, a portable terminal such as a cellular phone, a smartphone or a tablet, or a communication device such as, for example, a personal computer with a communication function.

A power feed circuit RF1 supplies high frequency signals in a frequency band of an f1 band to an antenna 155. The antenna 155 is capable of radiating the high frequency signals in the f1 band supplied from the power feed circuit RF1 into the air as radio waves. The frequency band of the f1 band is, for example, n41 (about 2.5 GHz to about 2.7 GHZ).

A filter device 100 according to Example Embodiment 2 is configured to attenuate high frequency signals in a frequency band of an f2 band. The f2 band is, for example, a 2.4 GHz band (about 2.4 GHz to about 2.5 GHz) of Wi-Fi (registered trademark).

In the filter device 100 according to Example Embodiment 2, the f1 band is a pass band and the f2 band is an attenuation band. The frequency band of the f1 band is lower than the frequency band of the f2 band.

The power feed circuit RF2 supplies the high frequency signals in the frequency band of the f2 band to the antenna 165. The antenna 165 is capable of radiating the high frequency signals in the f2 band supplied from the power feed circuit RF2 into the air as radio waves.

In the antenna device 150, the high frequency signals in the f2 band radiated from the antenna device 160 provided in the same antenna module 200 can be noise. Therefore, the filter device 100 is provided to remove the high frequency signals in the f2 band, which can be noise in the antenna device 150, by increasing the insertion loss due to parallel resonance.

The antenna 155 and the antenna 165 are mounted on, for example, the same substrate 170. In FIG. 11, the antenna 155 and the antenna 165 are provided on the same substrate 170, but they may be provided on different substrates as long as they are provided within the same antenna module 200. In Example Embodiment 2, the power feed circuit RF1 is not limited to supplying only the high frequency signals in the f1 band, but may also supply high frequency signals in other bands.

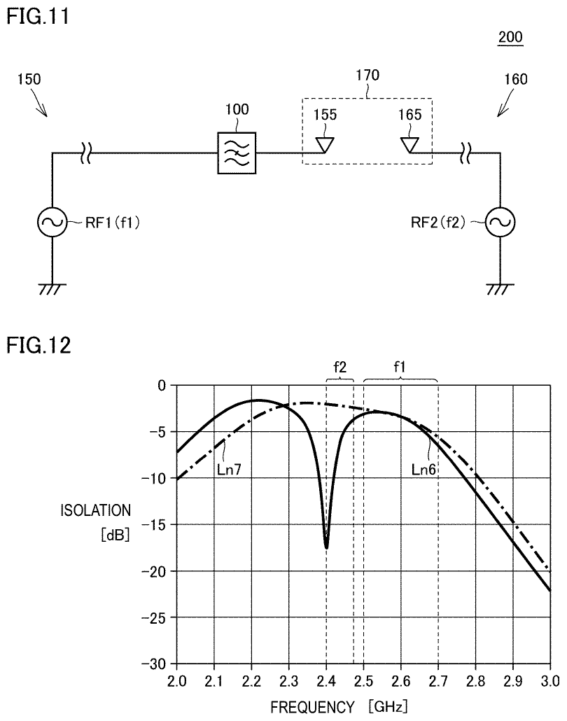

FIG. 12 is a graph showing the isolation characteristics between the antenna device 150 and the antenna device 160 according to Example Embodiment 2. In FIG. 12, the horizontal axis represents the frequency and the vertical axis represents the isolation.

A line Ln6 indicates the isolation between the antenna device 150 and the antenna device 160 of the antenna module 200 according to Example Embodiment 2. A line Ln7 indicates the isolation between an antenna device 150 and an antenna device 160 of a comparative example, in which the antenna device 150 is not provided with the filter device 100. In other words, the ratio of the power received by the power feed circuit RF1 of the antenna device 150 via the antenna to the power input from the power feed circuit RF2 of the antenna device 160 is the isolation.

As shown in FIG. 12, at a frequency of about 2.4 GHz in the f2 band, the isolation (Ln6) of the antenna module 200 is improved by 10 dB or more compared to the isolation (Ln7) of the antenna module of the comparative example. In other words, in Example Embodiment 2, the filter device 100 attenuates the frequencies in the f2 band, thereby improving the isolation between the antenna device 150 and the antenna device 160.

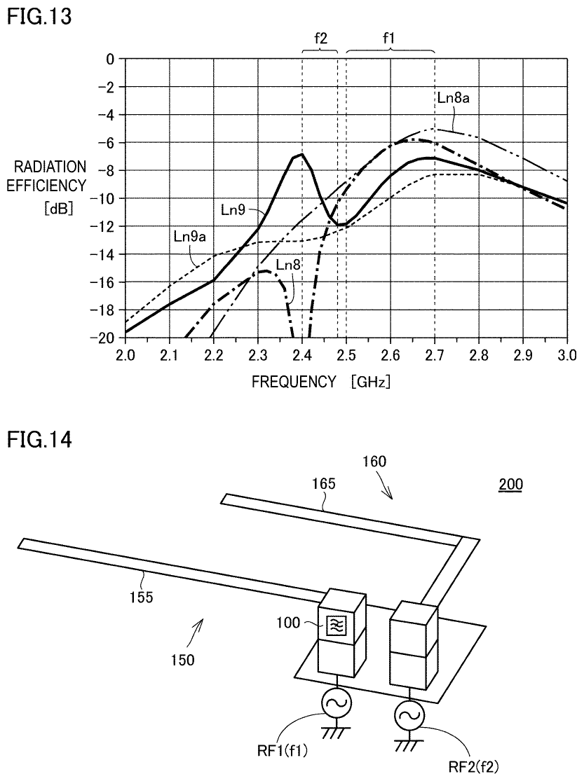

FIG. 13 is a graph showing the radiation efficiency of each of the antenna device 150 and the antenna device 160 according to Example Embodiment 2. In FIG. 13, the horizontal axis represents the frequency and the vertical axis represents the radiation efficiency. A line Ln8 indicates the radiation efficiency of the antenna device 150 of the antenna module 200 according to Example Embodiment 2. A line Ln9 indicates the radiation efficiency of the antenna device 160 of the antenna module 200 according to Example Embodiment 2. A line Ln8a indicates the radiation efficiency of the antenna device 150 of the comparative example, in which the antenna device 150 is not provided with the filter device 100. A line Ln9a indicates the radiation efficiency of the antenna device 160 of the comparative example, in which the antenna device 150 is not provided with the filter device 100. Here, the radiation efficiency means the ratio of the power radiated from the antenna to the power supplied from the power feed circuit. In other words, the upper part of the graph in FIG. 13, the more power is radiated from the antenna for the same supplied power.

As shown in FIG. 13, at the frequency of about 2.4 GHZ in the f2 band, the radiation efficiency (Ln9) of the antenna device 160 of the antenna module 200 is improved by about 6 dB compared to the radiation efficiency (Ln9a) of the antenna device 160 of the comparative example. In other words, in Example Embodiment 2, the filter device 100 is provided in the antenna device 150, thus improving the radiation efficiency of the antenna device 160.

### Example of Antenna Structure

FIG. 14 is an external view of the antenna module 200 according to Example Embodiment 2. As shown in FIG. 14, the antenna module 200 is provided with the antenna device 150 and the antenna device 160. The antenna device 150 includes the antenna 155, which is preferably, for example, a monopole antenna, the filter device 100, and the power feed circuit RF1. The antenna device 160 includes the antenna 165, which is preferably, for example, a monopole antenna, and the power feed circuit RF2. The antennas 155 and 165 are not limited to a monopole antenna, but may be, for example, an inverted-F antenna, a loop antenna, an array antenna or the like. The antenna 155 is connected to the power feed circuit RF1 via the filter device 100. The antenna 165 is connected to the power feed circuit RF2.

As described above, the antenna module 200 according to Example Embodiment 2 is capable of radiating the radio waves in the f1 band and the f2 band. The antenna module 200 is provided with the antenna device 150, which is capable of radiating the radio waves in the f1 band, and the antenna device 160, which is capable of radiating the radio waves in the f2 band. The antenna device 150 is the antenna device according to Example Embodiment 1.

Thus, the antenna module 200 according to Example Embodiment 2 can improve the isolation between the antenna device 150 and the antenna device 160, improve the radiation characteristics of the radio waves in the f1 band in the antenna device 150, and improve the radiation characteristics of the radio waves in the f2 band in the antenna device 160.

### Example Embodiment 3

In Example Embodiment 1, the filter device 100 has been described in which the first path TL1 and the second path TL2 are provided between the inductor L1 and the terminal P2 as shown in FIG. 1, wherein the first path TL1 is provided with the LC series resonator RS and the second path TL2 is a short path. In Example Embodiment 3 of the present invention, a filter device including an inductor provided in parallel with the short path of the filter device 100 according to Example Embodiment 1 is described. In the filter device of Example Embodiment 3, the same or corresponding components as those of the filter device 100 of Example Embodiment 1 are denoted by the same reference signs, and the detailed explanation thereof is not repeated. In the antenna device 150 of Example Embodiment 1 and the antenna module 200 of Example Embodiment 2, the filter device of Example Embodiment 3 may be used instead of the filter device 100.

FIG. 15 is a circuit diagram of a filter device 100A according to Example Embodiment 3. As shown in FIG. 15, the filter device 100A includes an inductor L1, an inductor L2, an inductor L3, and a capacitor C1. A first path TL1 and a second path TL2 are provided between the inductor L1 and a terminal P2. The first path TL1 is provided with an LC series resonator RS in which the inductor L2 and the capacitor C1 are connected in series. The second path TL2 is a short path. Furthermore, the inductor L3 is provided in parallel with the second path TL2, which is a short path.

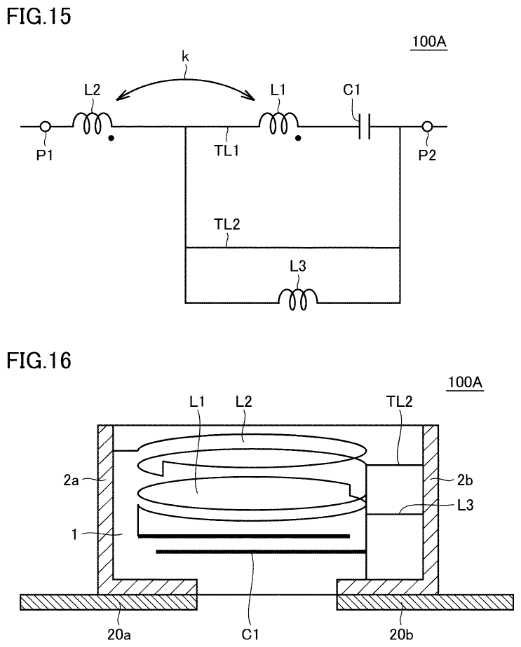

The inductor L1 and the inductor L2 are magnetically coupled to each other, but the inductor L3 is preferably not magnetically coupled to the inductor L1 and the inductor L2. FIG. 16 is a schematic view of the filter device 100A according to Example Embodiment 3. As shown in FIG. 16, the filter device 100A is integrated as a chip component, for example, in which the inductor L1, the inductor L2, the inductor L3, and the capacitor C1 shown in FIG. 15 are included in an insulator 1 (housing) obtained by stacking dielectric layers. Outer electrodes 2a and 2b are provided on the outer side portion of the insulator 1; a terminal P1 is connected to the outer electrode 2a (first outer electrode) and the terminal P2 is connected to the outer electrode 2b (second outer electrode).

As shown in FIG. 16, the wiring from the connection portion between the inductor L1 and the inductor L2 to the outer electrode 2b corresponds to the second path TL2, which is a short path, and the parasitic inductance of about 2 nH of the wiring parallel to the second path TL2 corresponds to the inductor L3. In other words, the inductor L3 exists at a position that does not overlap with the inductor L1 and the inductor L2 when viewed from the coil opening direction. The outer electrode 2a is electrically connected to a land electrode 20a of a circuit board for mounting the filter device 100A, and the outer electrode 2b is electrically connected to a land electrode 20b of the circuit board for mounting the filter device 100A.

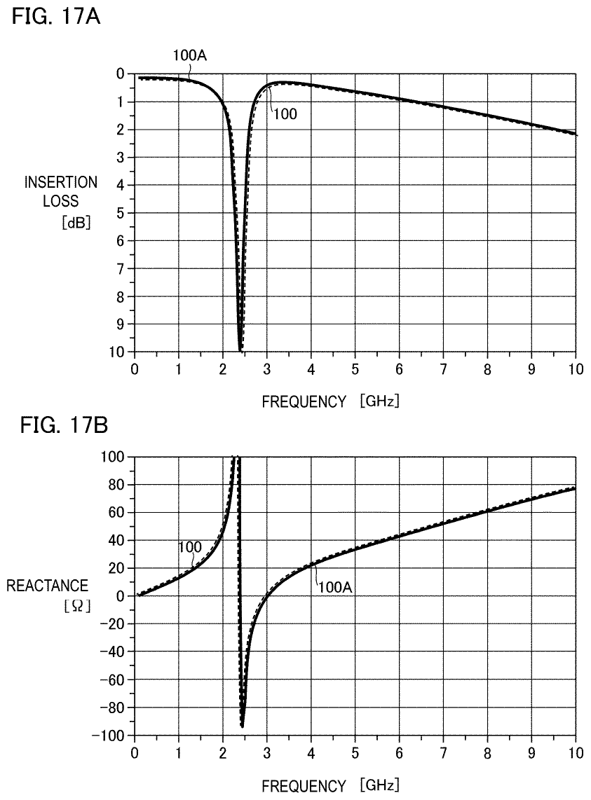

FIGS. 17A and 17B are graphs showing an example of the insertion loss and an example of the reactance characteristics of the filter device 100A according to Example Embodiment 3. The respective constants of the filter device 100A are, for example, L1=about 2.0 nH, L2=about 2.0 nH, C1=about 2.2 pF, k=about 0.6, 13=about 2 nH, and the insertion loss and the reactance characteristics are indicated by the solid lines in FIGS. 17A and 17B. As a comparative example, the respective constants of the filter device 100 shown in FIG. 1 are L1=about 2.0 nH, L2=about 2.0 nH, C1=about 2.2 pF, and k=about 0.6, and the insertion loss and the reactance characteristics are indicated by the dashed lines in FIGS. 17A and 17B. FIG. 17A shows an example of the insertion loss of the filter device 100A according to Example Embodiment 3. In FIG. 17A, the horizontal axis represents the frequency and the vertical axis represents the insertion loss. FIG. 17B shows an example of the reactance characteristics of the filter device 100A according to Example Embodiment 3. In FIG. 17B, the horizontal axis represents the frequency and the vertical axis represents the reactance.

As shown in FIGS. 17A and 17B, the resonant frequency of the filter device 100A is about 2.4 GHz, which is the same resonant frequency as the filter device 100 of Example Embodiment 1. In other words, it is known that there is no change in the insertion loss and the reactance characteristics even when the inductor L3 (a third path with a parasitic inductance of about 2 nH) is provided in parallel with the second path TL2, which is a short path, as in the filter device 100A. On the other hand, the filter device 100A can reduce ESL by providing the inductor L3. Thus, additional paths can be provided regardless of parasitic inductance, and ESL can be reduced.

### Example Embodiment 4

In Example Embodiment 1, the filter device 100 has been described in which the first path TL1 and the second path TL2 are provided between the inductor L1 and the terminal P2 as shown in FIG. 1, wherein the first path TL1 is provided with the LC series resonator RS and the second path TL2 is a short path. In Example Embodiment 4 of the present invention, a filter device including a capacitor provided in parallel with the short path of the filter device 100 according to Example Embodiment 1 is described. In the filter device of Example Embodiment 4, the same or corresponding components as those of the filter device 100 of Example Embodiment 1 are denoted by the same reference signs, and the detailed explanation thereof is not repeated. In the antenna device 150 of Example Embodiment 1 and the antenna module 200 of Example Embodiment 2, the filter device of Example Embodiment 4 may be used instead of the filter device 100.

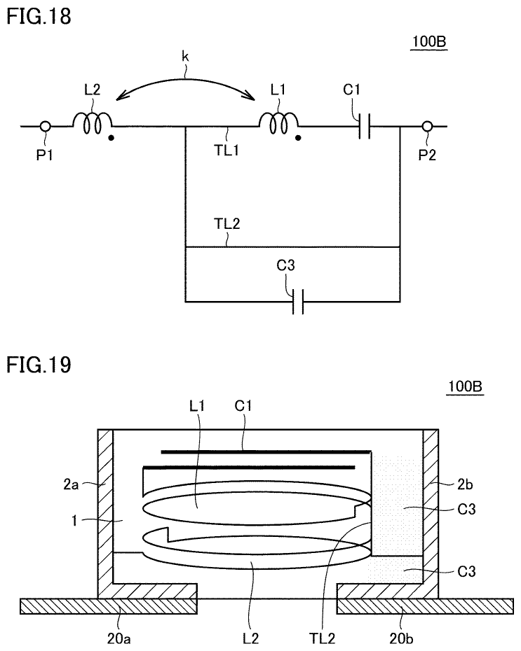

FIG. 18 is a circuit diagram of a filter device 100B according to Example Embodiment 4. As shown in FIG. 18, the filter device 100B includes an inductor L1, an inductor L2, a capacitor C1, and a capacitor C3. A first path TL1 and a second path TL2 are provided between the inductor L1 and a terminal P2. The first path TL1 is provided with an LC series resonator RS in which the inductor L2 and the capacitor C1 are connected in series. The second path TL2 is a short path. Furthermore, the capacitor C3 is provided in parallel with the second path TL2, which is a short path.

The inductor L1 and the inductor L2 are magnetically coupled to each other. FIG. 19 is a schematic view of the filter device 100B according to Example Embodiment 4. As shown in FIG. 19, the filter device 100B is integrated as a chip component, for example, in which the inductor L1, the inductor L2, the capacitor C1, and the capacitor C3 shown in FIG. 18 are included in an insulator 1 (housing) obtained by stacking dielectric layers. Outer electrodes 2a and 2b are provided on the outer side portion of the insulator 1. A terminal P1 is connected to the outer electrode 2a (first outer electrode) and the terminal P2 is connected to the outer electrode 2b (second outer electrode).

As shown in FIG. 19, the wiring from the connection portion between the inductor L1 and the inductor L2 to the outer electrode 2b corresponds to the second path TL2, which is a short path, and the parasitic capacitance formed between the second path TL2 and the outer electrode 2b corresponds to the capacitor C3. The outer electrode 2a is electrically connected to a land electrode 20a of a circuit board for mounting the filter device 100B, and the outer electrode 2b is electrically connected to a land electrode 20b of the circuit board for mounting the filter device 100B.

The resonant frequency of the filter device 100B is about 2.4 GHz, the same or substantially the same as that of the filter device 100A shown in FIGS. 17A and 17B, which is the same resonant frequency of the filter device 100 of Example Embodiment 1, if the values of L1, L2, C1 and k are the same, regardless of the value of C3. The reactance characteristics of the filter device 100B are also the same as those of the filter device 100. In other words, it is known that there is no change in the insertion loss and the reactance characteristics even when the capacitor C3 (e.g., a parasitic capacitance) is provided in parallel with the second path TL2, which is a short path, as in the filter device 100B. In other words, normally the inductors should be placed as far away from the outer electrodes as possible, as shown in FIG. 16, but since the characteristics do not fluctuate due to the parasitic capacitance C3, the inductors can be placed close to the outside, as shown in FIG. 19.

### Example Embodiment 5

In Example Embodiment 3, the filter device 100A has been described in which the inductor L3 is provided in parallel with the second path TL2, which is a short path, as shown in FIG. 15. In Example Embodiment 5 of the present invention, a filter device in which an inductor is provided parallel with the entire path, instead of parallel with the short path as in the filter device 100A according to Example Embodiment 3, is described. In the filter device of Example Embodiment 5, the same or corresponding components as those of the filter device 100 of Example Embodiment 1 are denoted by the same reference signs, and the detailed explanation thereof is not repeated. In the antenna device 150 of Example Embodiment 1 and the antenna module 200 of Example Embodiment 2, the filter device of Example Embodiment 5 may be used instead of the filter device 100.

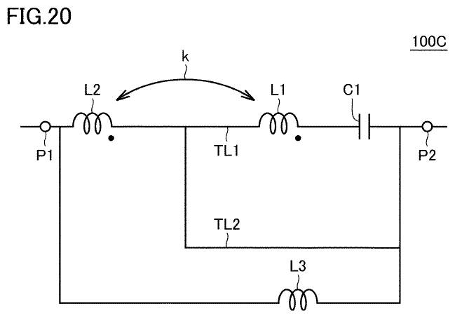

FIG. 20 is a circuit diagram of a filter device 100C according to Example Embodiment 5. As shown in FIG. 20, the filter device 100C includes an inductor L1, an inductor L2, an inductor L3 (third inductor), and a capacitor C1. A first path TL1 and a second path TL2 are provided between the inductor L1 and a terminal P2. The first path TL1 is provided with an LC series resonator RS in which the inductor L2 and the capacitor C1 are connected in series. The second path TL2 is a short path. Furthermore, the inductor L3 is provided in parallel with the entire path between a terminal P1 and the terminal P2. In other words, the inductor L3 is connected in parallel with the inductor L1 and the inductor L2. The inductor L1 and the inductor L2 are magnetically coupled to each other, but the inductor L3 is not magnetically coupled to the inductor L1 and the inductor L2.

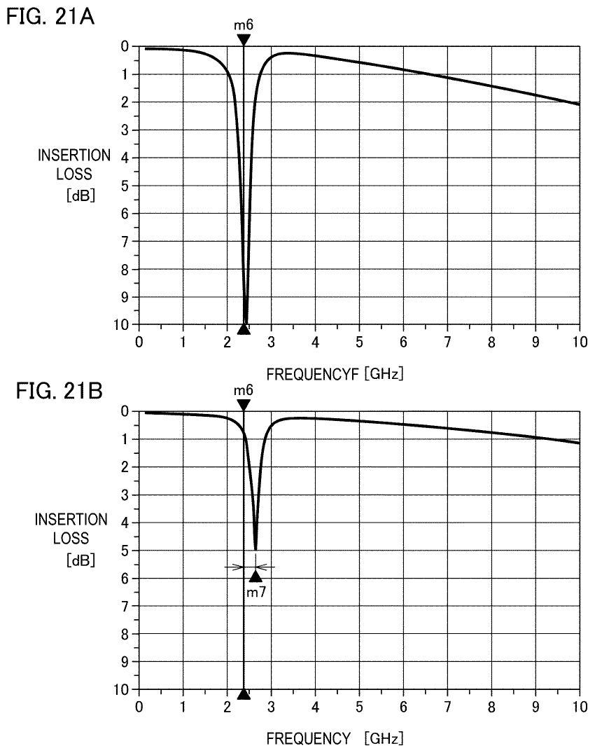

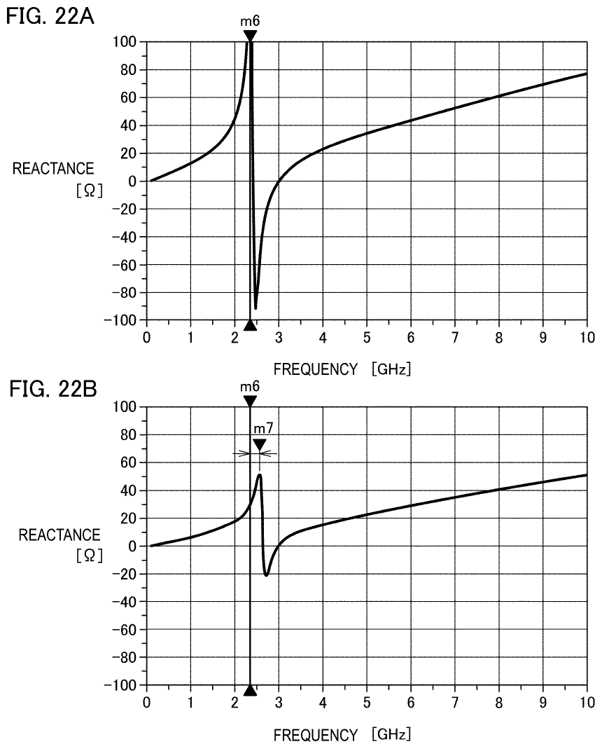

FIGS. 21A and 21B are graphs showing an example of the insertion loss of the filter device 100C according to Example Embodiment 5. In FIGS. 21A and 21B, the horizontal axis represents the frequency and the vertical axis represents the insertion loss. The graph shown in FIG. 21A is an example of the insertion loss of the filter device 100 according to Example Embodiment 1, in which the respective constants of the filter device 100 are L1=about 2 nH, L2=about 2 nH, C1=about 2.2 pF, k=about 0.6. The graph shown in FIG. 21B is an example of the insertion loss of the filter device 100C according to Example Embodiment 5, in which L3=about 2.5 nH in addition to the respective constants in FIG. 21A. FIGS. 22A and 22B are graphs showing an example of the reactance characteristics of the filter device 100C according to Example Embodiment 5. In FIGS. 22A and 22B, the horizontal axis represents the frequency and the vertical axis represents the reactance. The graph shown in FIG. 22A is an example of the reactance characteristics of the filter device 100 according to Example Embodiment 1, and the graph shown in FIG. 22B is an example of the reactance characteristics of the filter device 100C according to Example Embodiment 5.

As shown in FIGS. 21 and 22, the resonant frequency of the filter device 100 is about 2.4 GHZ (mark m6), while the resonant frequency of the filter device 100C is about 2.7 GHZ (mark m7), shifted to the higher frequency side by about 0.3 GHZ. In other words, the resonant frequency can be adjusted by connecting the inductor L3 in parallel with the entire path, as in the filter device 100C. The filter device 100C can be an integrated chip, or a structure including a circuit board and defined by adding a separate inductor element to the filter device 100. By adding a separate inductor element to the filter device 100, the resonant frequency can be adjusted as desired.

### Example Embodiment 6

In Example Embodiment 4, the filter device 100B has been described in which the capacitor C3 is provided in parallel with the second path TL2, which is a short path, as shown in FIG. 18. In Example Embodiment 6 of the present invention, a filter device in which a capacitor is provided in parallel with the entire path, instead of the filter device 100B according to Example Embodiment 4 in which the capacitor C3 is provided in parallel with the short path, is described. In the filter device of Example Embodiment 6, the same components as those of the filter device 100 of Example Embodiment 1 are denoted by the same reference signs, and the detailed explanation thereof is not repeated. In the antenna device 150 of Example Embodiment 1 and the antenna module 200 of Example Embodiment 2, the filter device of Example Embodiment 6 may be used instead of the filter device 100.

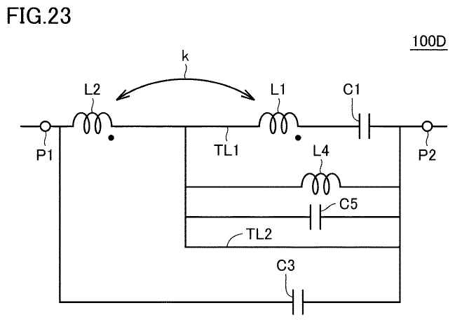

FIG. 23 is a circuit diagram of a filter device 100D according to Example Embodiment 6. As shown in FIG. 23, the filter device 100D preferably includes an inductor L1, an inductor L2, a capacitor C1, and a capacitor C3 (second capacitor). A first path TL1 and a second path TL2 are provided between the inductor L1 and a terminal P2. The first path TL1 is provided with an LC series resonator RS in which the inductor L2 and the capacitor C1 are connected in series. The second path TL2 is a short path. Furthermore, the capacitor C3 is provided in parallel with the entire path between a terminal P1 and the terminal P2. In other words, the capacitor C3 is connected in parallel with the inductor L1 and the inductor L2.

Furthermore, the filter device 100D is provided with an inductor L4 and a capacitor C5 in parallel with the second path TL2, which is a short path, described in Example Embodiments 3 and 4. As described in Example Embodiments 3 and 4, the filter device 100D does not change in the insertion loss and the reactance characteristics even when the inductor L4 and the capacitor C5 are provided. Note that the filter device 100D may be configured to be provided with either the inductor L4 or the capacitor C5. As in the filter device 100C of Example Embodiment 5, the inductor L4 and the capacitor C5 may be provided in parallel with the second path TL2, which is a short path, described in Example Embodiments 3 and 4.

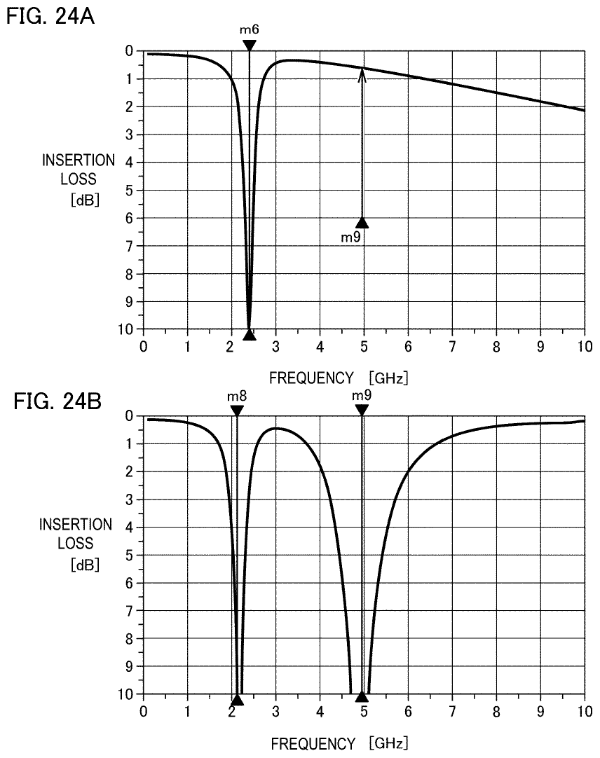

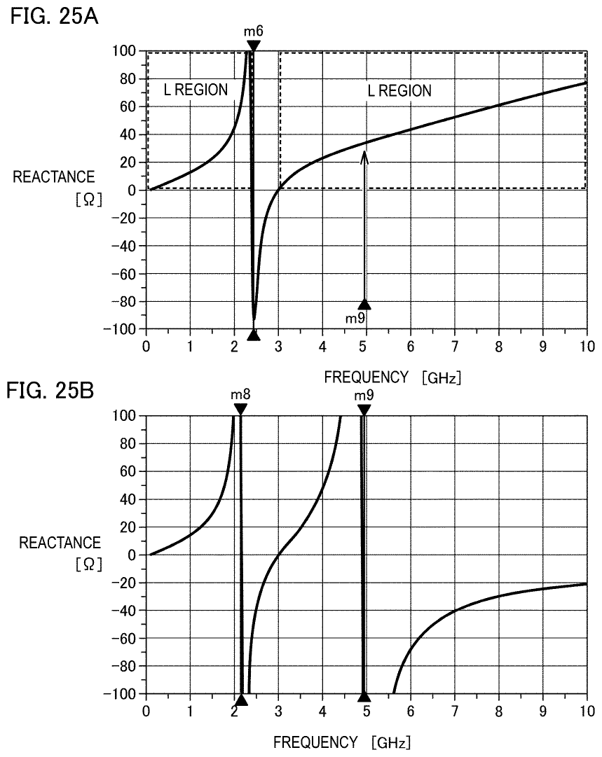

FIGS. 24A and 24B are graphs showing an example of the insertion loss of the filter device 100D according to Example Embodiment 6. In FIGS. 24A and 24B, the horizontal axis represents the frequency and the vertical axis represents the insertion loss. The graph shown in FIG. 24A is an example of the insertion loss of the filter device 100 according to Example Embodiment 1, in which the respective constants are L1=about 2.0 nH, L2=about 2.0 nH, C1=about 2.2 pF, k=about 0.6. The graph shown in FIG. 24B is an example of the insertion loss of the filter device 100D according to Example Embodiment 6, in which C3=about 4 pF, C5=about 2 pF, and L4=about 2 nH in addition to the above constants. FIGS. 25A and 25B are graphs showing an example of the reactance characteristics of the filter device 100D according to Example Embodiment 6. In FIGS. 25A and 25B, the horizontal axis represents the frequency and the vertical axis represents the reactance. The graph shown in FIG. 25A is an example of the reactance characteristics of the filter device 100 according to Example Embodiment 1, and the graph shown in FIG. 25B is an example of the reactance characteristics of the filter device 100D according to Example Embodiment 6.

As shown in FIGS. 24 and 25, the filter device 100 has one resonant frequency at about 2.4 GHZ (mark m6), while the filter device 100D has two resonant frequencies at about 2.2 GHZ (mark m8) and about 4.9 GHZ (mark m9). In other words, an attenuation region can be added in the L region shown in FIGS. 25A and 25B by connecting the capacitor C3 in parallel with the entire path, as in the filter device 100D. Since the resonant frequency of the filter device 100D is shifted to the lower frequency side by providing the capacitor C3, the resonant frequency can be adjusted arbitrarily by adding a separate capacitor element to the filter device 100 over the entire path as described in Example Embodiment 5.

### Variations

It has been described that the filter device 100 according to Example Embodiment 1 has a configuration in which the inductor L1, the inductor L2, and the capacitor C1 are provided in this order between the terminal P1 and the terminal P2, as shown in FIG. 1. However, in the filter device 100, the order of the inductor L2 and the capacitor C1 may be changed, or the inductor L1 side may be connected to the terminal P2. Note that, in the filter device 100, whether to connect the inductor L1 to the terminal P2 side (antenna 155 side) or to the terminal P1 side (power feed circuit RF1 side) can be determined depending on the antenna impedance.

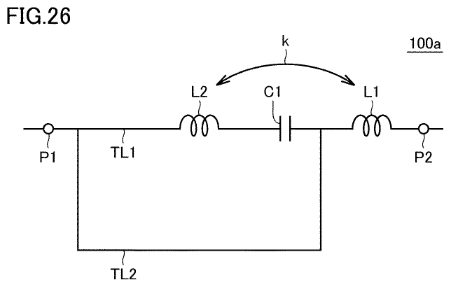

FIG. 26 is a circuit diagram of a filter device 100a according to a variation. As shown in FIG. 26, in the filter device 100a, an inductor L2, a capacitor C1, and an inductor L1 are provide in this order between a terminal P1 and a terminal P2.

In the filter device 100a, a first path TL1 and a second path TL2 are provided between the terminal P1 and the inductor L1. The first path TL1 is provided with a LC series resonator RS, in which the inductor L2 and the capacitor C1 are connected in series in this order. The second path TL2 is a short path. The inductor L1 and the inductor L2 are magnetically coupled to each other. The filter device 100a can obtain the same effect as the filter device 100 except for the effect of the parasitic capacitance and the parasitic inductance generated in the second path TL2, which is a short path, by changing the order of the inductor L2.

It has been explained that the filter devices 100 and 100a are designed by considering only the inductor L1, the inductor L2, and the capacitor C1. However, an actual filter device needs to be designed by further considering stray capacitance, parasitic inductance and the like.

The filter devices 100 and 100a may include other components such as, for example, a matching circuit to match the impedance with the antenna 155, the power feed circuit RF1 and the like, and a phase shifter to switch the phase of the high frequency signal.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A filter device having a pass band in a first frequency band and an attenuation band in a second frequency band lower than the first frequency band, comprising:
a first terminal;
a second terminal;
a first inductor connected to the first terminal; and
a series resonator including a first capacitor and a second inductor provided in, among a first path and a second path provided in parallel between the first inductor and the second terminal, the first path; wherein
the first inductor and the second inductor are magnetically coupled to each other.

2. The filter device according to claim 1, wherein an inductance of the second path is smaller than a mutual inductance between the first inductor and the second inductor.

3. The filter device according to claim 1, wherein an inductance of the first inductor is smaller than an inductance of the second inductor.

4. The filter device according to claim 1, wherein
the first terminal and the second terminal are electrically connected to a first outer electrode and a second outer electrode provided on a housing, respectively; and
the first inductor and the series resonator are provided in the housing.

5. The filter device according to claim 4, wherein
the housing is an insulator;
the first inductor and the series resonator include a plurality of conductor patterns in the insulator;
the first inductor is electrically connected to the first outer electrode and includes one or more layers of first conductor patterns;
the second inductor is electrically connected to the second outer electrode and includes one or more layers of second conductor patterns; and
the first capacitor is electrically connected to a wiring extending from the first conductor pattern or the second conductor pattern.

6. The filter device according to claim 5, wherein
in the insulator, a substrate on which the second conductor pattern is provided is stacked on a substrate on which the first conductor pattern is provided, such that the first inductor and the second inductor are arranged opposing each other; and
an opening of the first inductor at least partially overlaps with an opening of the second inductor, when viewed from a stacking direction of the insulator.

7. The filter device according to claim 6, wherein the first capacitor is provided on a layer different from a layer on which the first inductor and the second inductor are provided.

8. The filter device according to claim 7, wherein the first capacitor is located on a side of the first inductor when viewed from the stacking direction of the insulator.

9. The filter device according to claim 1, further comprising a third path connected in parallel with the second path.

10. The filter device according to claim 9, wherein the third path is not magnetically coupled to the first inductor and the second inductor.

11. The filter device according to claim 10, wherein the third path does not overlap with the first inductor and the second inductor when viewed from opening directions of the first inductor and the second inductor.

12. The filter device according to claim 1, further comprising a third inductor connected in parallel with the first inductor and the second inductor.

13. The filter device according to claim 4, further comprising:
a third inductor connected in parallel with the first inductor and the second inductor; wherein
one end of the third inductor is connected to the first outer electrode and another end of the third inductor is connected to the second outer electrode; and
the third inductor is provided outside the housing as a separate element.

14. The filter device according to claim 1, further comprising a second capacitor connected in parallel with the first inductor and the second inductor.

15. The filter device according to claim 4, further comprising:
a second capacitor connected in parallel with the first inductor and the second inductor; wherein
one end of the second capacitor is connected to the first outer electrode and another end of the second capacitor is connected to the second outer electrode; and
the second capacitor is provided outside the housing as a separate element.

16. An antenna device capable of radiating a radio wave in the first frequency band, comprising:
an antenna;
a power feed circuit to supply a high frequency signal to the antenna; and
the filter device according to claim 1 provided between the antenna and the power feed circuit.

17. An antenna module comprising:
a first antenna device capable of radiating a radio wave in the first frequency band; and
a second antenna device capable of radiating a radio wave in the second frequency band; wherein
the first antenna device is the antenna device according to claim 16.

18. The filter device according to claim 1, wherein
the filter device is integrated as a chip component with the first inductor and the series resonator are provided in an insulator including stacking dielectric layers; and
the first terminal and the second terminal are located on an outer side portion of the insulator.

19. The filter device according to claim 1, wherein the first inductor, the second inductor, and the first capacitor are stacked one upon another with the second inductor being between the first inductor and the first capacitor.

20. The filter device according to claim 1, wherein
the first inductor and the second inductor are located side by side with respect to the first capacitor.
